(19) United States
(12) Patent Application Publication
(10) Pub. No.: US 2004/0178514 A1
(43) Pub. Date: Sep. 16, 2004

(54) Method of encapsulating semiconductor devices on a printed circuit board, and a printed circuit board for use in the method

(76) Inventors: Sang-Hyeop Lee, Cheonan-City (KR); Hee-Kook Choi, Cheonan-City (KR)

Correspondence Address: VOLENTINE FRANCOS, P.L.L.C., Suite 150, 12200 Sunrise Valley Drive, Reston, VA, 20191, US

(21) Appl. No.: 10/665,632

(22) Filed: Sep. 22, 2003

(30) Foreign Application Priority Data
Mar. 12, 2003 (KR) 2003-15394

(51) Int. Cl. H01L 23/28; H01L 21/56

(52) U.S. Cl. 257/787; 438/126

(57) ABSTRACT

A first semiconductor chip is attached to a first side of a printed circuit board, and a second semiconductor chip is attached to a second side of the printed circuit board opposite the first side of the printed circuit board. A mold is then used to form a first mold cavity which contains the first semiconductor chip over the first side of the printed circuit board, and to form a second mold cavity which contains the second semiconductor chip over the second side of the printed circuit board. The first and second mold cavities are simultaneously filled with a fill material via a mold inlet, where the mold inlet is at least partially defined through an aperture in the printed circuit board from the first side to the second side.

### BACKGROUND OF THE INVENTION

1. Field of the Invention

The present invention generally relates to the manufacture of semiconductor devices. More particularly, the present invention relates to a method of encapsulating semiconductor chip packages attached to a printed circuit board, and to a printed circuit board used in the method.

2. Description of the Related Art

Electronic modules are generally formed by the mounting of several semiconductor chip packages to a printed circuit board, and recently, the trend has been to attach the chip packages to both sides of the printed circuit board to increase packing density.

The wafer level package (WLP) is one type of chip package mounted onto printed circuit boards. WLP's are characterized by external terminals that are distributed in a two-dimensional array over a surface of the semiconductor chip. This reduces the signal path of the semiconductor chip to a package I/O location, thereby improving the operational speed of the device. Further, unlike other chip packages having peripheral leads extending from the sides of the package, the WLP occupies no more of the surface of the printed circuit board (PCB) than roughly the size of the chip itself.

The WLP typically contains metallic solder bumps which function as external terminals interconnecting the package to the printed circuit board. The solder bumps of the WLP device are attached to the printed circuit board and then encapsulated within an epoxy material to secure a reliable connection with the printed circuit board and to protect the WLP from an external environment. FIGS. 1 through 4 are cross-sectional views for explaining a conventional method of encapsulating WLP packages on opposite sides of a printed circuit board.

FIG. 1 shows a cross-sectional view of a typical wafer level package 14. The wafer level package generally includes a semiconductor chip 10 and a plurality of solder bumps 12 formed over a surface of the semiconductor chip 10. Though not shown, the solder bumps 12 are disposed in an array fashion on the surface of the semiconductor chip 10, and one or several rerouting layers are interposed between the solder bump array and the semiconductor chip 10.

Referring to FIG. 2, wafer level packages 14 are attached to opposite sides of the a printed circuit board 18 as shown. In this manner, semiconductor chips 10 are electrically connected to the printed circuit board 18 through the solder bumps 12.

Referring to FIG. 3, the printed circuit board 18 is positioned in a mold body which generally includes an upper mold body portion 22 and a lower mold body portion (not shown). The upper mold body 22 has a mold cavity defined therein, and the upper mold body portion 22 is positioned on a side of the printed circuit board 18 so as to accommodate the wafer level package 14 attached on the upper side of the printed circuit board 18.

The upper mold body portion also has a mold inlet 24 which is defined adjacent the upper surface of the printed circuit board 18 and which is in fluid communication with the mold cavity. As represented by the arrow of FIG. 3, the mold cavity is filled with an encapsulating material 26 through this mold inlet 24. Preferably, the encapsulating material 26 is an epoxy molding compound (EMC).

Subsequently, though not shown, the resultant structure is turned upside down, and then the wafer level package on the other side of the printed circuit board is encapsulated in the same manner. FIG. 4 is a cross-sectional view of the completed electronic module, where the wafer level packages are encapsulated within the molded EMC on both sides of the printed circuit board 18.

As described above, in order to encapsulate the wafer level packages on both sides of the printed circuit board, it is necessary to execute the same molding process twice, i.e., once on each side of the printed circuit board. The inherent redundancy of the process has the net effect of increasing processing time and manufacturing costs.

### SUMMARY OF THE INVENTION

According to on aspect of the present invention, a first semiconductor chip is attached to a first side of a printed circuit board, and a second semiconductor chip is attached to a second side of the printed circuit board opposite the first side of the printed circuit board. A mold is then used to form a first mold cavity which contains the first semiconductor chip over the first side of the printed circuit board, and to form a second mold cavity which contains the second semiconductor chip over the second side of the printed circuit board. The first and second mold cavities are simultaneously filled with a fill material via a mold inlet, where the mold inlet is at least partially defined through an aperture in the printed circuit board from the first side to the second side.

According to another aspect of the present invention, a first semiconductor chip is attached to a first side of a non-disposable portion of printed circuit board, and a second semiconductor chip is attached to a second side of the non-disposable portion of the printed circuit board opposite the first side of the printed circuit board. A mold is used to form a first mold cavity which contains the first semiconductor chip over the first side of the printed circuit board, and to form a second mold cavity which contains the second semiconductor chip over the second side of the printed circuit board. The mold further forms a mold inlet which traverses a boundary between a disposable region and the non-disposable region of the printed circuit board. The first and second mold cavities are simultaneously filled with a fill material via the mold inlet. Then, the mold is removed to expose the fill material defined by the first and second cavities and further defined by the mold inlet. The disposable region of the printed circuit board is then separated from the non-disposable region of the printed circuit board.

According to another aspect of the present invention, a semiconductor chip is attached to a first side of a non-disposable portion of printed circuit board. A mold is used to form a mold cavity which contains the semiconductor chip over the first side of the printed circuit board, where the mold further forms a mold inlet which traverses a boundary between a disposable region and the non-disposable region of the printed circuit board. The mold cavity is then filled with a fill material via the mold inlet, and the mold is removed to expose the fill material defined by the mold cavity and further defined by the mold inlet. The disposable region of the printed circuit board is then separated from the non-disposable region of the printed circuit board.

According to still another aspect of the present invention, a plurality of first semiconductor chips are attached to a first side of a printed circuit board, and a plurality of second semiconductor chips are attached to a second side of the printed circuit board opposite the first side of the printed circuit board. A mold is then used to form at least one first mold cavity which contains the first semiconductor chips over the first side of the printed circuit board, and to form at least one second mold cavity which contains the second semiconductor chips over the second side of the printed circuit board. The first and second mold cavities are then simultaneously filled with a fill material via at least one mold inlet.

According to yet another aspect of the present invention, a plurality of first semiconductor chips are attached to a first side of a non-disposable portion of printed circuit board, and a plurality of second semiconductor chips are attached to a second side of the non-disposable portion of the printed circuit board opposite the first side of the printed circuit board. A mold is then used to form at least one first mold cavity which contains the first semiconductor chips over the first side of the printed circuit board, and to form at least one second mold cavity which contains the second semiconductor chips over the second side of the printed circuit board. The mold further forms at least one mold inlet which traverses a boundary between a disposable region and the non-disposable region of the printed circuit board. The first and second mold cavities are then simultaneously filled with a fill material via the mold inlet. The mold is then removed to expose the fill material defined by the first and second cavities and further defined by the mold inlet, and the disposable region of the printed circuit board is separated from the non-disposable region of the printed circuit board.

According to still another aspect of the present invention, a plurality of semiconductor chips are attached to a first side of a non-disposable portion of printed circuit board. A mold is used to form at least one first mold cavity which contains the semiconductor chips over the first side of the printed circuit board, where the mold further forms at least one mold inlet which traverses a boundary between a disposable region and the non-disposable region of the printed circuit board. The at least one mold cavity is filled with a fill material via the mold inlet, and then the mold is removed to expose the fill material defined by the at least one mold cavity and further defined by the mold inlet, The disposable region of the printed circuit board is then separated from the non-disposable region of the printed circuit board.

According to another aspect of the present invention, an elongate printed circuit board is provided having an edge connector located on a first long edge thereof. A plurality of first wafer level packages are attached on a first surface of the printed circuit board and juxtaposed along the length of the printed circuit board between the first long edge and a second long edge of the printed circuit board. A plurality of second wafer level packages are attached on a second surface of the printed circuit board opposite the first surface and aligned with the first wafer level packages, respectively. A mold is used to form at least one first mold cavity which contains the first wafer level packages over the first side of the printed circuit board, and to form at least one second mold cavity which contains the second wafer level packages over the second side of the printed circuit board. The first and second mold cavities then simultaneously filled with a fill material via at least one mold inlet which extends from the second edge of the printed circuit board to the first and second mold cavities.

According to still another aspect of the present invention, a printed circuit board includes a flat, elongate board body having a first surface and an opposite second surface, and further having a first long edge and an opposite second long edge. An edge connector is located on the first long edge of the board body. A first plurality of wafer level package mounting regions are located on the first surface of the board body and juxtaposed along the length of the board body between the first long edge and a second long edge, and a second plurality of wafer level package mounting regions are located on the second surface of the board body and respectively aligned with the first plurality of wafer level package mounting regions. A plurality of mold inlet apertures extend through said board body and are respectively located between second long edge and the wafer level package mounting regions.

### BRIEF DESCRIPTION OF THE DRAWINGS

The various aspects and features of the present invention will become readily apparent from the detailed description that follows, with reference to the accompanying drawings, in which:

FIG. 1 is a cross-sectional schematic view of a conventional wafer level package (WLP);

FIGS. 2 through 4 are cross-sectional schematic views for explaining a conventional process for encapsulating wafer level packages on a printed circuit board;

FIG. 5 is a cross-sectional schematic view of a printed circuit board according to an embodiment of the present invention;

FIG. 6 is a top schematic view of a printed circuit board according to an embodiment of the present invention;

FIGS. 7 and 8 are cross-sectional schematic views for explaining a process for encapsulating wafer level packages on a printed circuit board according to another embodiment of the present invention;

FIG. 9 is a top schematic view of a printed circuit board according to another embodiment of the present invention;

FIG. 10 is a top schematic view of a printed circuit board according to another embodiment of the present invention;

FIGS. 11 through 13 are cross-sectional schematic views for explaining a process for encapsulating wafer level packages on a printed circuit board according to another embodiment of the present invention;

FIG. 14 is a top schematic view of a printed circuit board according to another embodiment of the present invention; and

FIG. 15 is a top schematic view of a printed circuit board according to another embodiment of the present invention.

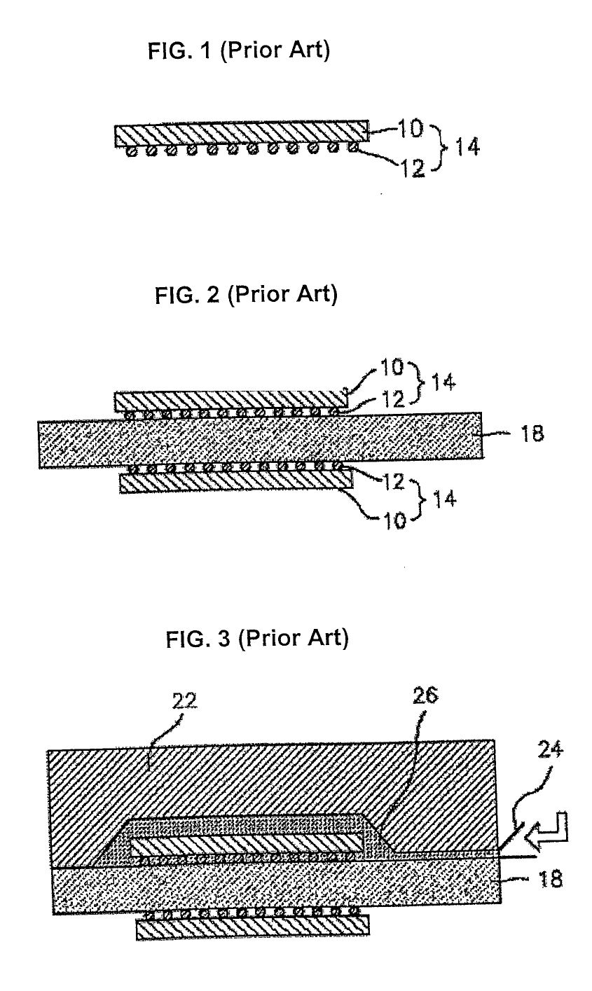

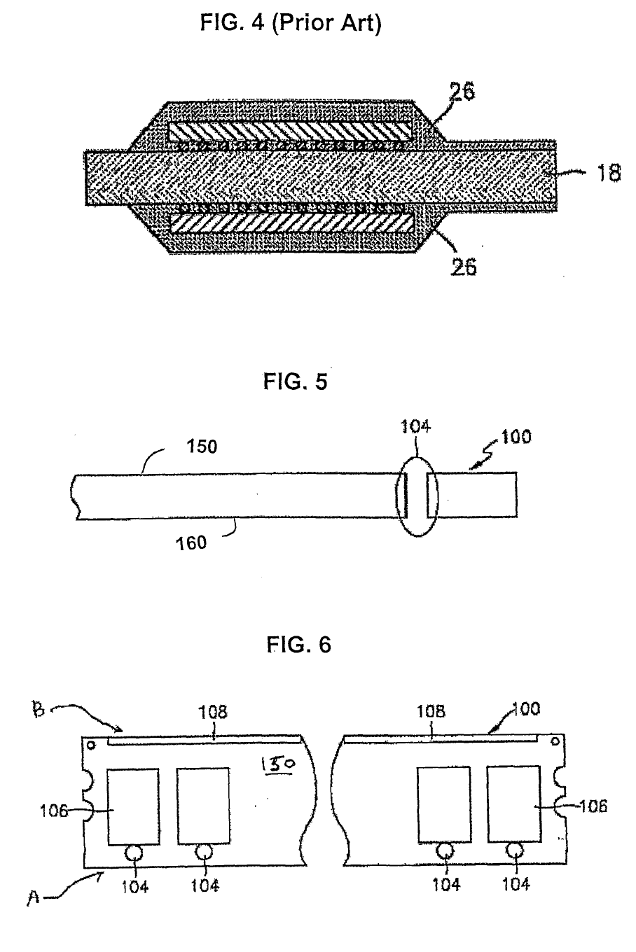

### DETAIL DESCRIPTION OF THE PREFERRED EMBODIMENTS

The present invention will is described in detail below by way of several non-limiting preferred embodiments.

A printed circuit board (PCB) of an embodiment of the present invention will now be described with reference to the schematic illustrations of FIGS. 5 and 6, where FIG. 5 is a partial cross-sectional view of FIG. 6. As will be explained later, the PCB of this embodiment may be used to fabricate semiconductor devices in accordance with methods of manufacture of the present invention.

Referring to FIGS. 5 and 6, a generally flat and elongate board body 100 includes a first surface 150 and an opposite second surface 160, and a first long edge A and an opposite second long edge B. Preferably, the thickness, length and width dimensions of the board body 100 are in conformance with standards set by the Joint Electronic Device Engineering Council (JEDEC). The board body 100 is generally formed of multiple conductive patterned layers and insulating layers which are stacked on top of each other.

An edge connector 108 is located on the first long edge B of the board body 100. Device mounting regions 106 are located on the first surface 150 of the board body 100 and juxtaposed along the length of the board body 100 between the first long edge A and the second long edge B. Each mounting region is preferably a conductive pad for the mounting of a wafer level package (WLP) device. Although not shown in FIGS. 5 and 6, device mounting regions are also located on the second surface 160 of the board body 100 and respectively aligned with the device mounting regions 106 on the first side 150 of the board body 100. In other words, the device attaching areas 106 on the first surface 150 are substantially a mirror image of those on the second surface 160.

A plurality of mold inlet apertures 104 extend through the board body 100 from the first side 150 to the second side 160. In this embodiment, the mold inlet apertures 104 are provided in one-to-one correspondence with each aligned pair device attaching areas 106. Also, in this embodiment, the mold inlet apertures 104 are located between second long edge A (opposite a connector 110, discussed later) and the respective wafer level package mounting regions 106, preferably in close proximity to the wafer level mounting regions 106.

An edge connector 108 is located on the first long edge B of the board body 100. Though not shown, the edge connector 108 is preferably configured as a comb of printed connector tabs. Electronic modules are typically interconnected by mounting to a motherboard by means of a female edge connector physically affixed to and electrically connected with the motherboard. The edge connector 108 performs the dual functions of electrically connecting the module with the motherboard and physically supporting the module.

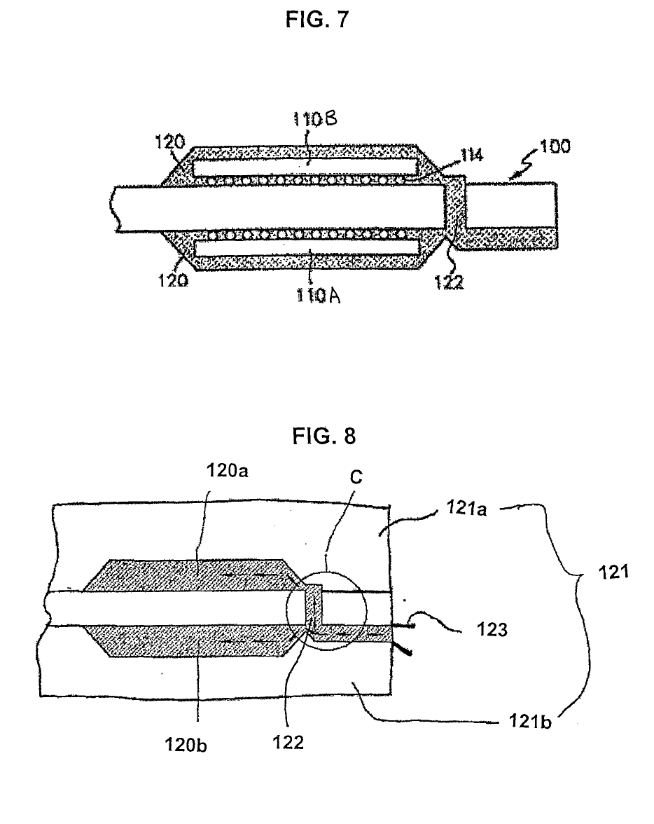

A process for encapsulating wafer level packages on a printed circuit board according to another embodiment of the present invention will now be described with reference to the cross-sectional schematic views of FIGS. 7 and 8.

Referring to FIGS. 7 and 8, first semiconductor chip 110A is attached to a first side of a printed circuit board 100, and a second semiconductor chip 110B is attached to an opposite second side of the printed circuit board 100. The printed circuit board 100 is equipped with a mold inlet aperture 122, and may be configured like the printed circuit board 100 discussed above in connection with FIGS. 5 and 6. In this case, the first and second semiconductor chips 110A, 110B are aligned with one another. Also, the first and second semiconductor chips 110A, 110B are preferably wafer level packages mounted on conductive pads of the printed circuit board 100.

After attaching the semiconductor chips 110A, 110B to the printed circuit board 100, the printed circuit board 100 is positioned in a mold body 121. The mold body 121 includes an upper mold body 121a and a lower mold body 121b. The upper mold body 121a has a first mold cavity 120a defined therein, and the lower mold body 121b has a second mold cavity 120b defined therein. The upper mold body 121a is positioned on a side of the printed circuit board 100 so as to accommodate the semiconductor chip 110B within the upper mold cavity 120a. Likewise, the lower mold body 121b is positioned on an opposite side of the printed circuit board 100 so as to accommodate the semiconductor chip 110A within the lower mold cavity 121b. At this time, the upper and lower mold cavities 120a, 120b are in fluid communication with the mold inlet aperture 122 of the printed circuit board 100.

The upper mold body 121a or the lower mold body 121b also has a mold inlet 123 which is defined adjacent a surface of the printed circuit board 18 and which is in fluid communication with the mold inlet aperture 122.

Next, the mold cavities 120a, 120b are simultaneously filled. That is, referring to the arrows and the region C of FIG. 8, an encapsulating material is fed into the mold inlet 123 so as to flow into the mold cavities 120a, 120b. The mold cavity on the opposite side of the printed circuit board 100 to the mold inlet 123 is filled through the mold inlet aperture 122. As should be apparent from FIG. 8, the mold inlet aperture 122 of the printed circuit board 100 allows for the simultaneous filling of the mold cavities 120a and 120b.

Upon setting of the encapsulating material, the mold body 121 is removed. FIG. 7 is a cross-sectional view of the completed electronic module. In a preferred embodiment, wafer level packages 110A, 110B are encapsulated within molded EMC 120 on both sides of the printed circuit board 100.

In the description above, only first and second semiconductor chips 110A, 110B are shown and discussed. However, referring to FIG. 6, a preferred process is to mounted a plurality of semiconductor chips on the respective pads 106 of both sides of the printed circuit board. In this case, the upper mold body may define a plurality of upper mold cavities each in fluid communication with a respective one of the mold inlet apertures 104. Likewise, the lower mold body may define a plurality of lower mold cavities each in fluid communication with a respective one of the mold inlet apertures 104. The upper mold body and/or the lower mold body may then include one or more mold inlets in fluid communication with the mold inlet apertures 104. In this manner, the plurality of upper mold cavities and the plurality of lower mold cavities can all be filled with encapsulating material as the same time.

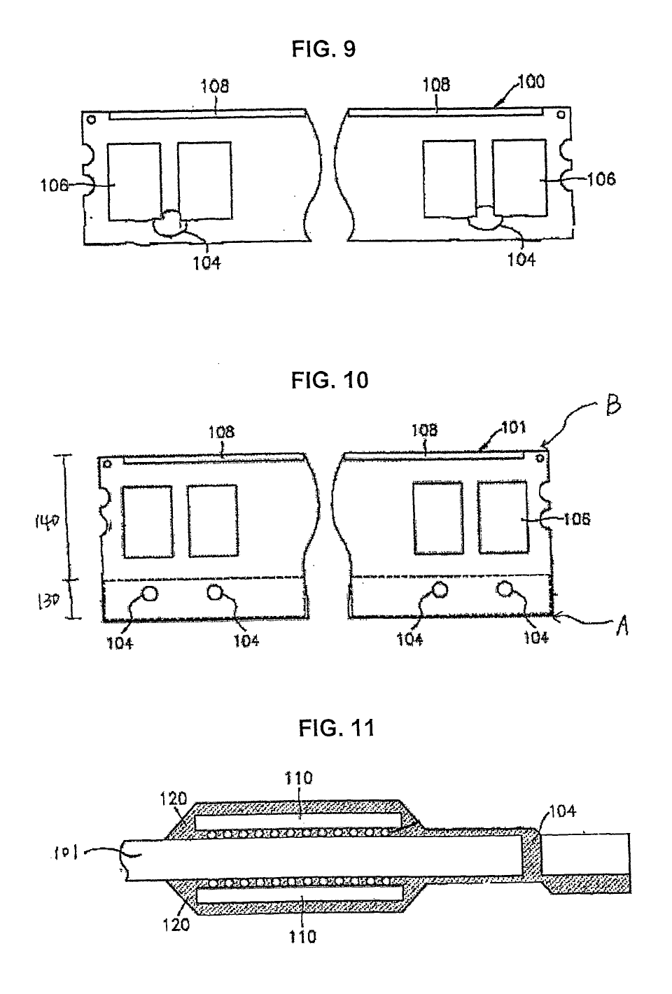

In the embodiment of FIG. 6, the mold inlet apertures 104 are provided in one-to-one correspondence with the device mounting areas 106. However, the invention is not limited in this manner. For example, as shown in FIG. 9, two or more adjacent device mounting areas 106 may share the same mold inlet aperture 104.

FIG. 10 is a top schematic view of a printed circuit board according to another embodiment of the present invention. In this embodiment, a plurality of device mounting regions 106 are provided on at least one side of a board body 101, and an edge connector 108 is located at one edge B of the board body 101.

The board body 101 is divided into a disposable portion 130 and a non-disposable portion 140. As shown, the disposable portion is located along the edge A of the board body 101, opposite the connector 108. Preferably, the thickness, length and width dimensions of the non-disposable portion 140 of the board body 100 are in conformance with standards set by the Joint Electronic Device Engineering Council (JEDEC).

Finally, a plurality of mold inlet apertures 104 are located in the disposable portion 130. In this example, the mold inlet apertures are provided in one-to-one correspondence with the device mounting regions 106.

A process for encapsulating wafer level packages on a printed circuit board according to another embodiment of the present invention will now be described with reference to the cross-sectional schematic views of FIGS. 11 through 13.

Referring first to FIG. 11, first and second wafer level packages 110 are attached to opposite sides of a printed circuit board, and then encapsulated with an epoxy mold compound in the same manner as described above in connection with FIGS. 7 and 8. The printed circuit board may be configured in the same manner as that shown in FIG. 6.

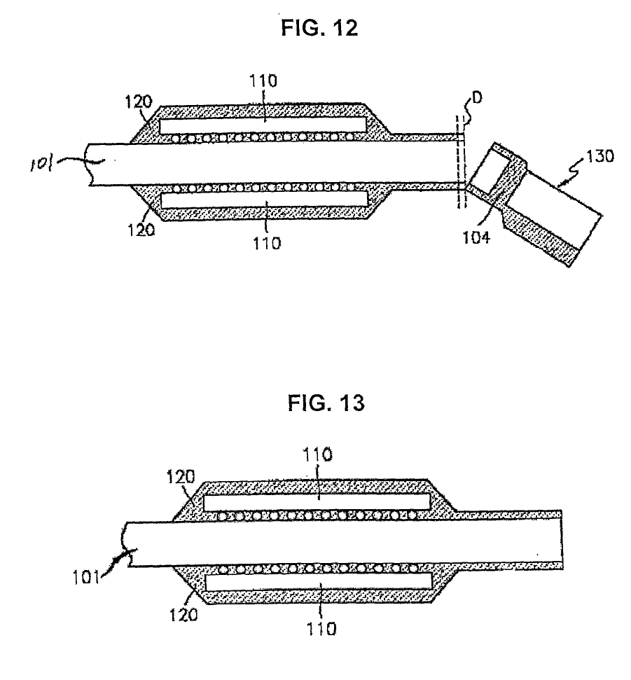

Next, referring to FIG. 12, a saw blade or press apparatus is used to remove the disposable region 130 from the circuit board body 101. The resultant final module product is shown in FIG. 13.

The embodiment of FIGS. 11 through 13 is advantageous in that portions of the printed circuit board of the final product are not occupied by the mold inlet apertures. That is, the high density and complexity in the conductive patterns of the printed circuit board may make it difficult to find room for and design around the mold inlet apertures. This difficulty may be overcome by locating the mold inlet apertures in a disposable region of the board body, and then separating the disposable region to obtain the final product.

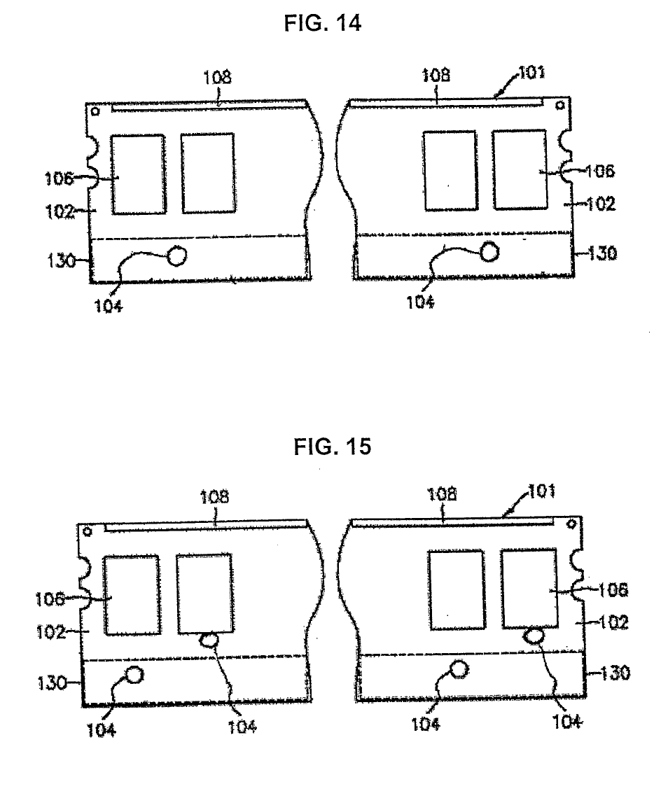

In the embodiment of FIG. 10, the mold inlet apertures 104 are provided in one-to-one correspondence with the device mounting areas 106. However, the invention is not limited in this manner. For example, as shown in FIG. 14, two or more adjacent device mounting areas 106 may share the same mold inlet aperture 104.

Likewise, in the embodiment of FIG. 10, all of the mold inlet apertures are located in the disposable region 130. However, the invention is not limited in this manner. For example, as shown in FIG. 15, some of the mold inlet apertures may be located in the non-disposable region 140, while others are located in the disposable region 130. This type of configuration may provide flexibility when optimizing the quality of the mold process.

In the drawings and specification, there have been disclosed typical preferred embodiments of this invention and, although specific examples are set forth, they are used in a generic and descriptive sense only and not for purposes of limitation. For example, in the embodiments above, the mold cavities on opposite sides of the printed circuit board are simultaneously filled using an aperture in the printed circuit board. However, it is also possible to simultaneously fill the mold cavities by providing respective mold inlets extending from an edge of the printed circuit board on opposite sides of the printed circuit board. As another example, it is further possible to apply the embodiments in which the disposable portion of the printed circuit board is used to form part of the mold inlet to the case where a semiconductor chip is attached to one side only of the printed circuit board. It should therefore be understood the scope of the present invention is to be construed by the appended claims, and not by the exemplary embodiments.

What is claimed is:

1. A method of manufacturing a semiconductor device, said method comprising:
attaching a first semiconductor chip to a first side of a printed circuit board;
attaching a second semiconductor chip to a second side of the printed circuit board opposite the first side of the printed circuit board;
using a mold to form a first mold cavity which contains the first semiconductor chip over the first side of the printed circuit board, and to form a second mold cavity which contains the second semiconductor chip over the second side of the printed circuit board; and
simultaneously filling the first and second mold cavities with a fill material via a mold inlet, wherein the mold inlet is at least partially defined through an aperture in the printed circuit board from the first side to the second side.

2. The method as claimed in claim 1, wherein the first semiconductor chip attached to the first side of the printed circuit board is aligned with the second semiconductor chip on the second side of the printed circuit board.

3. The method as claimed in claim 1, further comprising removing the mold after filling of the first and second cavities, and then separating a portion of the printed circuit board containing the aperture from a portion of the printed circuit board containing the first and second semiconductor chips.

4. The method as claimed in claim 1, wherein the mold inlet extends from a first edge of the printed circuit board to the aperture in the printed circuit board, and further from the aperture to the first and second mold cavities.

5. The method as claimed in claim 4, wherein a second edge of the printed circuit board, opposite the first edge, includes an edge connector.

6. The method as claimed in claim 1, wherein the fill material is an epoxy mold compound.

7. The method as claimed in claim 1, wherein the first and second semiconductor chips are wafer level packages.

8. A method of manufacturing a semiconductor device, said method comprising:
attaching a first semiconductor chip to a first side of a non-disposable portion of printed circuit board;
attaching a second semiconductor chip to a second side of the non-disposable portion of the printed circuit board opposite the first side of the printed circuit board;
using a mold to form a first mold cavity which contains the first semiconductor chip over the first side of the printed circuit board, and to form a second mold cavity which contains the second semiconductor chip over the second side of the printed circuit board, wherein the mold further forms a mold inlet which traverses a boundary between a disposable region and the non-disposable region of the printed circuit board;
simultaneously filling the first and second mold cavities with a fill material via the mold inlet;
removing the mold to expose the fill material defined by the first and second cavities and further defined by the mold inlet; and
separating the disposable region of the printed circuit board from the non-disposable region of the printed circuit board.

9. The method as claimed in claim 8, wherein the first semiconductor chip attached to the first side of the printed circuit board is aligned with the second semiconductor chip on the second side of the printed circuit board.

10. The method as claimed in claim 8, wherein the mold inlet extends from a first edge of the printed circuit board to the non-disposable portion of the printed circuit board.

11. The method as claimed in claim 10, wherein a second edge of the printed circuit board, opposite the first edge, includes an edge connector.

12. The method as claimed in claim 8, wherein the first and second semiconductor chips are wafer level packages.

13. A method of manufacturing a semiconductor device, said method comprising:
attaching a semiconductor chip to a first side of a non-disposable portion of printed circuit board;
using a mold to form a mold cavity which contains the semiconductor chip over the first side of the printed circuit board, wherein the mold further forms a mold inlet which traverses a boundary between a disposable region and the non-disposable region of the printed circuit board;
filling the mold cavity with a fill material via the mold inlet;
removing the mold to expose the fill material defined by the mold cavity and further defined by the mold inlet; and
separating the disposable region of the printed circuit board from the non-disposable region of the printed circuit board.

14. The method as claimed in claim 13, wherein the mold inlet extends from a first edge of the printed circuit board to the non-disposable portion of the printed circuit board.

15. The method as claimed in claim 14, wherein a second edge of the printed circuit board, opposite the first edge, includes an edge connector.

16. The method as claimed in claim 13, wherein the semiconductor chip is a wafer level package.

17. A method of manufacturing a semiconductor device, said method comprising:
attaching a plurality of first semiconductor chips to a first side of a printed circuit board;
attaching a plurality of second semiconductor chips to a second side of the printed circuit board opposite the first side of the printed circuit board;
using a mold to form at least one first mold cavity which contains the first semiconductor chips over the first side of the printed circuit board, and to form at least one second mold cavity which contains the second semiconductor chips over the second side of the printed circuit board; and
simultaneously filling the first and second mold cavities with a fill material via at least one mold inlet.

18. The method as claimed in claim 17, wherein the mold inlet is at least partially defined by at least one aperture through the printed circuit board from the first side to the second side.

19. The method as claimed in claim 17, wherein the first plurality of semiconductor chips attached to the first side of the printed circuit board are respectively aligned with the second plurality of semiconductor chips on the second side of the printed circuit board.

20. The method as claimed in claim 17, wherein the at least one first mold cavity includes a plurality of first mold cavities which respectively contain the plurality of first semiconductor chips, and wherein the at least one second mold cavity includes a plurality of second mold cavities which respectively contain the plurality of second semiconductor chips.

21. The method as claimed in claim 20, wherein the at least one mold inlet includes a plurality of mold inlets in fluid communication with the pluralities of first and second mold cavities, respectively.

22. The method as claimed in claim 21, wherein the plurality of mold inlets are at least partially defined by a plurality of respective apertures which extend through the printed circuit board from the first side to the second side.

23. The method as claimed in claim 22, wherein the plurality of mold inlets extend from a first edge of the printed circuit board to the respective plurality of apertures in the printed circuit board, and further from the respective plurality of apertures to the respective pluralities of first and second mold cavities.

24. The method as claimed in claim 23, wherein a second edge of the printed circuit board, opposite the first edge, includes an edge connector.

25. The method as claimed in claim 24, further comprising removing the mold after filling of the pluralities of first and second cavities, and then separating a portion of the printed circuit board containing the plurality of apertures from a portion of the printed circuit board containing the pluralities of first and second semiconductor chips.

26. The method as claimed in claim 17, wherein the first and second semiconductor chips are wafer level packages.

27. The method as claimed in claim 19, wherein the mold inlet is at least partially defined by a plurality of apertures through the printed circuit board from the first side to the second side, and wherein the plurality of mold inlet apertures are provided in one-to-one correspondence with the aligned first and second semiconductor packages.

28. The method as claimed in claim 19, wherein the mold inlet is at least partially defined by a plurality of apertures through the printed circuit board from the first side to the second side, and wherein the plurality of mold inlet apertures are provided in a less than one-to-one correspondence with the aligned first and second semiconductor packages.

29. The printed circuit board as claimed in claim 17, wherein the mold inlet is at least partially defined by a plurality of apertures through the printed circuit board from the first side to the second side, wherein some of the plurality of apertures are located in a disposable portion of the board body, and others of the plurality of apertures are located in a non-disposable portion of the board body, and wherein the first and second semiconductor packages are attached in the non-disposable portion of the board body.

30. The printed circuit board as claimed in claim 17, wherein thickness, length and width dimensions of the printed circuit board are in conformance with a Joint Electronic Device Engineering Council (JEDEC) standard.

31. A method of manufacturing a semiconductor device, said method comprising:
attaching a plurality of first semiconductor chips to a first side of a non-disposable portion of printed circuit board;
attaching a plurality of second semiconductor chips to a second side of the non-disposable portion of the printed circuit board opposite the first side of the printed circuit board;
using a mold to form at least one first mold cavity which contains the first semiconductor chips over the first side of the printed circuit board, and to form at least one second mold cavity which contains the second semiconductor chips over the second side of the printed circuit board, wherein the mold further forms at least one mold inlet which traverses a boundary between a disposable region and the non-disposable region of the printed circuit board;
simultaneously filling the first and second mold cavities with a fill material via the mold inlet;
removing the mold to expose the fill material defined by the first and second cavities and further defined by the mold inlet; and
separating the disposable region of the printed circuit board from the non-disposable region of the printed circuit board.

32. The method as claimed in claim 31, wherein the first plurality of semiconductor chips attached to the first side of the printed circuit board are aligned with the second plurality of semiconductor chips on the second side of the printed circuit board.

33. The method as claimed in claim 31, wherein the mold inlet extends from a first edge of the printed circuit board to the non-disposable portion of the printed circuit board.

34. The method as claimed in claim 33, wherein a second edge of the printed circuit board, opposite the first edge, includes an edge connector.

35. The method as claimed in claim 31, wherein the first and second semiconductor chips are wafer level packages.

36. The method as claimed in claim 32, wherein the mold inlet is at least partially defined by a plurality of apertures through the printed circuit board from the first side to the second side, and wherein the plurality of mold inlet apertures are provided in one-to-one correspondence with the aligned first and second semiconductor packages.

37. The method as claimed in claim 32, wherein the mold inlet is at least partially defined by a plurality of apertures through the printed circuit board from the first side to the second side, and wherein the plurality of mold inlet apertures are provided in a less than one-to-one correspondence with the aligned first and second semiconductor packages.

38. The printed circuit board as claimed in claim 31, wherein the mold inlet is at least partially defined by a plurality of apertures through the printed circuit board from the first side to the second side, wherein some of the plurality of apertures are located in the disposable portion of the board body, and others of the plurality of apertures are located in the non-disposable portion of the board body, and wherein the first and second semiconductor packages are attached in the non-disposable portion of the board body.

39. The printed circuit board as claimed in claim 31, wherein thickness, length and width dimensions of the printed circuit body are in conformance with a Joint Electronic Device Engineering Council (JEDEC) standard.

40. A method of manufacturing a semiconductor device, said method comprising:
attaching a plurality of semiconductor chips to a first side of a non-disposable portion of printed circuit board;
using a mold to form at least one first mold cavity which contains the semiconductor chips over the first side of the printed circuit board, wherein the mold further forms at least one mold inlet which traverses a boundary between a disposable region and the non-disposable region of the printed circuit board;
filling the at least one mold cavity with a fill material via the mold inlet;
removing the mold to expose the fill material defined by the at least one mold cavity and further defined by the mold inlet; and
separating the disposable region of the printed circuit board from the non-disposable region of the printed circuit board.

41. The method as claimed in claim 40, wherein the at least one mold inlet includes a plurality of mold inlets extending from a first edge of the printed circuit board to the non-disposable portion of the printed circuit board.

42. The method as claimed in claim 41, wherein a second edge of the printed circuit board, opposite the first edge, includes an edge connector.

43. The method as claimed in claim 40, wherein the plurality of semiconductor chips are wafer level packages.

44. A method of manufacturing a semiconductor device, comprising:
providing an elongate printed circuit board having an edge connector located on a first long edge thereof;
attaching a plurality of first wafer level packages on a first surface of the printed circuit board, the first wafer level packages attached so as to be juxtaposed along the length of the printed circuit board between the first long edge and a second long edge of the printed circuit board;
attaching a plurality of second wafer level packages on a second surface of the printed circuit board opposite the first surface, the second wafer level packages attached so as to be juxtaposed along the length of the printed circuit board and aligned with the first wafer level packages, respectively;
using a mold to form at least one first mold cavity which contains the first wafer level packages over the first side of the printed circuit board, and to form at least one second mold cavity which contains the second wafer level packages over the second side of the printed circuit board;
simultaneously filling the first and second mold cavities with a fill material via at least one mold inlet which extends from the second edge of the printed circuit board to the first and second mold cavities.

45. The method as claimed in claim 44, wherein the at least one first mold cavity includes a plurality of first mold cavities which respectively contain the plurality of first wafer level packages, and wherein the at least one second mold cavity includes a plurality of second mold cavities which respectively contain the plurality of second wafer level packages.

46. The method as claimed in claim 45, wherein the at least one mold inlet includes a plurality of mold inlets extending between the second edge of the printed circuit board and the pluralities of first and second mold cavities, respectively.

47. The method as claimed in claim 46, wherein a plurality of apertures extending through the printed circuit board which partially define the plurality of mold inlets, respectively.

48. A method of manufacturing a semiconductor device, said method comprising:
providing a printed circuit board having a first side and a second side opposite the first side;
attaching a semiconductor chip to the first side of the printed circuit board;
using a mold to form a first mold cavity which contains the semiconductor chip over the first side of the printed circuit board; and
filling the first mold cavity with a fill material via a mold inlet, wherein the mold inlet is at least partially defined through an aperture in the printed circuit board from the first side to an opposite second side, wherein the aperture is located outside of a portion of the printed circuit board underlying the attached semiconductor chip.

49. The method as claimed in claim 48, wherein the first semiconductor chip is a wafer level package.

50. The method as claimed in claim 48, wherein the aperture is located in a disposable portion of the printed circuit board, and wherein the method further comprises separating the disposable portion of the printed circuit board from a remaining portion of the printed circuit board which contains the semiconductor chip.

51. A printed circuit board comprising:
a flat, elongate board body having a first surface and an opposite second surface, and further having a first long edge and an opposite second long edge;
an edge connector located on said first long edge of said board body;
a first plurality of semiconductor package mounting regions on the first surface of the board body and juxtaposed along the length of the board body between the first long edge and a second long edge;
a second plurality of semiconductor package mounting regions on the second surface of said board body and respectively aligned with the first plurality of wafer level package mounting regions; and
a plurality of mold inlet apertures extending through said board body and located between second long edge and said semiconductor package mounting regions.

52. The printed circuit board as claimed in claim 51, wherein the plurality of mold inlet apertures are provided in one-to-one correspondence with the aligned first and second semiconductor package mounting regions.

53. The printed circuit board as claimed in claim 51, wherein the plurality of mold inlet apertures are provided in a less than one-to-one correspondence with the aligned first and second semiconductor package mounting regions.

54. The printed circuit board as claimed in claim 51, wherein the plurality of mold inlet apertures are located in a disposable portion of the board body, and the first and second semiconductor package mounting regions are located in a non-disposable portion of the board body.

55. The printed circuit board as claimed in claim 51, wherein some of the plurality of mold inlet apertures are located in a disposable portion of the board body, and others of the plurality of mold inlet apertures are located in a non-disposable portion of the board body, and wherein the first and second semiconductor package mounting regions are located in a non-disposable portion of the board body.

56. The printed circuit board as claimed in claim 51, wherein thickness, length and width dimensions of the board body are in conformance with a Joint Electronic Device Engineering Council (JEDEC) standard.

57. The printed circuit board as claimed in claim 54, wherein thickness, length and width dimensions of the non-disposable portion of the board body are in conformance with a Joint Electronic Device Engineering Council (JEDEC) standard.

58. The printed circuit board as claimed in claim 55, wherein thickness, length and width dimensions of the non-disposable portion of the board body are in conformance with a Joint Electronic Device Engineering Council (JEDEC) standard.

59. The printed circuit board as claimed in claim 51, wherein the first and second semiconductor packages are wafer level packages.

60. The printed circuit board as claimed in claim 54, wherein the first and second semiconductor packages are wafer level packages.

61. The printed circuit board as claimed in claim 55, wherein the first and second semiconductor packages are wafer level packages.
